(19) United States
(12) Patent Application Publication
(10) Pub. No.: US 2024/0291488 A1
(43) Pub. Date: Aug. 29, 2024

(54) VOLTAGE COMPENSATION OF DIFFERENTIAL VOLTAGE SWING

(71) Applicant: STMicroelectronics International N.V., Geneva (CH)

(72) Inventors: Ravinder KUMAR, Ambala City (IN); Saiyid Mohammad Irshad RIZVI, New Delhi (IN)

(73) Assignee: STMicroelectronics International N.V., Geneva (CH)

(21) Appl. No.: 18/582,446

(22) Filed: Feb. 20, 2024

Related U.S. Application Data
(60) Provisional application No. 63/487,178, filed on Feb. 27, 2023.

(51) Int. Cl. H03K 19/003; H03K 19/0175

(52) U.S. Cl. CPC H03K 19/00369; H03K 19/017545; H03K 19/017581

(57) ABSTRACT

The present disclosure is directed to a voltage driver, where a combination of first and second resistance blocks controls a differential voltage swing on the outputs of the voltage driver. Variations of an input voltage are compensated by adding different values of the first resistance block to the second resistance block, while keeping a summation of the first and second resistance blocks at a constant value. Three different circuit diagrams are disclosed to generate these different resistances. In each circuit diagram, one or more control signals change the resistance of the combination of first and second resistance blocks. In some embodiments, the value of the second resistance block is changed by the first resistance block to maintain an impedance matching between a transmitter and a receiver, while changing of the first resistance block compensates for the differential voltage swing.

### BACKGROUND

### Technical Field

The present disclosure is directed to an apparatus and method of voltage compensation for differential voltage swing control that benefits low-power and high-speed voltage drivers.

### Description of the Related Art

High-speed point-to-point communications are broadly used in physical layer (PHY) protocols and Serializer/Deserializer (SerDes) systems. In some video-based applications, such as displays, serial data is transmitted by display ports with a low voltage supply. The high-speed serial data transmission is based on a low voltage differential signaling, which results in a low differential voltage swing at the output of the transmitter. A voltage driver is used to receive the input voltage from the low voltage supply and generate the output voltage at the output ports of the transmitter with an acceptable differential voltage swing specification. A variation of the input voltage causes a change in the differential voltage swing. The change of the differential voltage swing is typically compensated by voltage regulators in the voltage driver. However, in low voltage applications, the voltage compensation with the voltage regulators is limited due to limited operation range of the voltage regulators.

In general, high-speed serial data transmission is based on differential signals between two output contacts. In some video applications, the two output contacts are a display positive (Dp) port and a display negative (Dn) port. The display positive and negative ports are coupled to a load of a receiver. To achieve an optimum transmission efficiency, the impedance line of the transmitter is matched with the impedance of the load of the receiver. A positive signal transmitted by the positive port is approximately in opposite phase with a negative signal transmitted by the negative port. In this differential condition, the data is transmitted by a voltage difference between the positive and negative signals. The low voltage differential signaling allows high speed data transmission with a rate of about 155 Mbps to 20 Gbps. The transmission data rate may be limited by impedance mismatch between the transmitter and the load. The impedance mismatch may cause reflection waves and mode conversion, which results in degrading the differential signaling.

### BRIEF SUMMARY

The present disclosure is directed to an apparatus and method of voltage compensation for differential voltage swing control that benefits low-power and high-speed voltage drivers. In particular, a voltage mode driver is disclosed, where a combination of first and second resistance blocks compensates variation of the differential voltage swing. In this embodiment, variations of an input voltage are compensated by adding different values of the first resistance block to the second resistance block, while keeping a summation of the first and second resistance blocks at a constant value. Three different circuit diagrams are disclosed to generate these different resistances. In each method, one or more control signals change the resistance of the combination of first and second resistance blocks.

In various embodiments, a voltage driver includes first and second outputs coupled to a load. The first and second outputs may be positive and negative ports, respectively, of a transmitter, where the load is an impedance of a receiver. The transmitter may receive serial data for a display and transmit the data with the positive and negative ports that correspond to, for example, a display port. Voltage variations of the input voltage result in the differential voltage swing at the outputs of the voltage driver. Typically, the differential voltage swing directly depends on the variations of the input voltage. The variation of the input voltage is compensated by mitigating the first resistance block. The mitigation of the first resistance block may result in distortion of an impedance matching between the transmitter and the load. The impedance mismatch reduces transmission efficiency. To overcome the impedance mismatch, the second resistance block is coupled to the first resistance block. In this embodiment, the value of the second resistance block is changed by the first resistance block. Hence, a resistance value of a combination of the first and second resistance blocks remaining a constant value. This constant value maintains the impedance matching between the transmitter and receiver, while changing of the first resistance block compensates the differential voltage swing.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale.

FIG. 1 is a block diagram of high-speed point-to-point communication system according to an embodiment disclosed herein.

FIG. 2 is a topology of a voltage driver according to an embodiment disclosed herein.

FIG. 3 is an equivalent circuit of resistance blocks of FIG. 2 according to an embodiment disclosed herein.

FIG. 4 is a circuit including resistance blocks of FIGS. 1-3 according to an embodiment disclosed herein.

FIG. 5 is an example of the slices described in FIG. 4 according to an embodiment disclosed herein.

FIG. 6 is a circuit including resistance blocks of FIGS. 1-3 according to an embodiment disclosed herein.

FIG. 7 is an example of the slices described in FIG. 6 according to an embodiment disclosed herein.

FIG. 8 is a circuit including resistance blocks of FIGS. 1-3 according to an embodiment disclosed herein.

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of manufacturing of voltage drivers, electronic components, and communication systems have not been described in detail to avoid obscuring the descriptions of other aspects of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same aspect. Furthermore, the particular features, structures, or characteristics may be combined in any suitable manner in one or more aspects of the present disclosure.

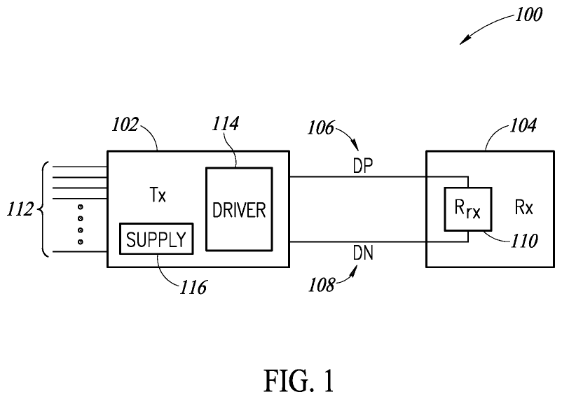

FIG. 1 schematically shows a block diagram of a high-speed point-to-point communication system 100 according to an embodiment disclosed herein. In some embodiments, the system 100 may include other types of high-speed communication systems. The system 100 includes a transmitter 102 (Tx) coupled to a receiver 104 (Rx) with differential connections. In this embodiment, the differential connections include a positive pad or terminal 106 (DP) and a negative pad or terminal 108 (DN) coupled to a load 110 (Rᵣₓ) of the receiver 104.

In various embodiments, the transmitter 102 receives serial data by serial inputs 112 and converts it to a low voltage differential signal to be transmitted to the receiver 104 by the positive and negative pads 106, 108. In some embodiments, the serial data may be video data to be transmitted to a display. In this condition the positive and negative pads are display ports.

In this embodiment, the transmitter 102 includes a voltage driver 114 in the transmitter 102 to generate differential voltages from the received serial data. The transmitter 102 operates in differential voltage mode transmission, which transmits the received serial data to a differential voltage in an output of the transmitter 102.

In low voltage applications, a low voltage supply 116 in the transmitter 102 provides an input voltage for the voltage driver 114. In some examples, the input voltage may be in a range between 1 and 3 V.

A voltage variation of the low voltage input degrades the differential voltage swing specification. In a conventional high power transmission mode, a voltage regulator (e.g., low dropout regulator) may compensate the variation of the input voltage to meet the desired differential voltage swing. However, in low voltage applications, the voltage regulator may not efficiently compensate the variation of the low voltage supply 116 due to burn power and voltage drop of the voltage regulator. In addition, usage of the voltage regulator increases complexity in the architecture of the voltage driver 114, which consequently impacts return loss (e.g., by the impact of input capacitance of transmitter (CTX) and power consumption). Hence, in various embodiments disclosed herein, a different method than using the voltage regulator is used to compensate the voltage variation of the low voltage supply 116 and control the differential voltage swing in the output of the transmitter 102.

In some embodiments, the voltage driver 114 includes a plurality of resistance blocks coupled to the positive and negative pads 106, 108. The differential voltage swing voltage is controlled by changing resistance value of the resistance blocks. For instance, a reduction of the low voltage supply 116 may be compensated by modifying the resistance of the resistance blocks. In some embodiments, the resistance blocks may include slices of resistors, in which the number of slices coupled to the output of the transmitter 102 is controlled by plurality of switches. Each slice corresponds to an equivalent impedance which is coupled into the output of the transmitter 102 and are designed to match output impedance of the transmitter 102 and with a transmission line that is coupled to the output of the transmitter 102. In some embodiments, the slices of the resistors are voltage-dependent variable impedance. For instance, the voltage-dependent variable impedance may be plurality of NMOS or PMOS transistors. In various embodiments, the low voltage supply 116 may change by ±20% while the differential voltage swing is changed by ±10%. In this condition, if the differential voltage swing increases, then a compensation technique may keep the differential voltage swing in an acceptable range. In various embodiments, the acceptable range of the differential voltage swing is about ±5%-10%. The low voltage supply 116 may be about 0.8-1.2 V.

In various embodiments, an output impedance of the transmitter 102 is designed to be matched with the impedance of the load 110. Impedance matching results in an optimum power and data transmission. In contrast, an impedance mismatch between the transmitter 102 and the load 110 causes reflection wave and mode conversion of the transmission, which degrades power and data transmission. The output impedance of the transmitter 102 depends on impedance of the transmission line, e.g., conductive lines coupled to the positive and negative pads 106, 108, and the resistance blocks of the transmitter 102. In this condition, the resistance blocks are designed to be matched with the impedance of the load 110. Thus, any change of the resistance blocks to control the differential voltage swing, results in an impedance mismatch between the transmitter 102 and the load 110.

In the present disclosure, method and apparatus are disclosed to control the differential voltage swing as well as maintain the impedance matching between the transmitter 102 and the load 110.

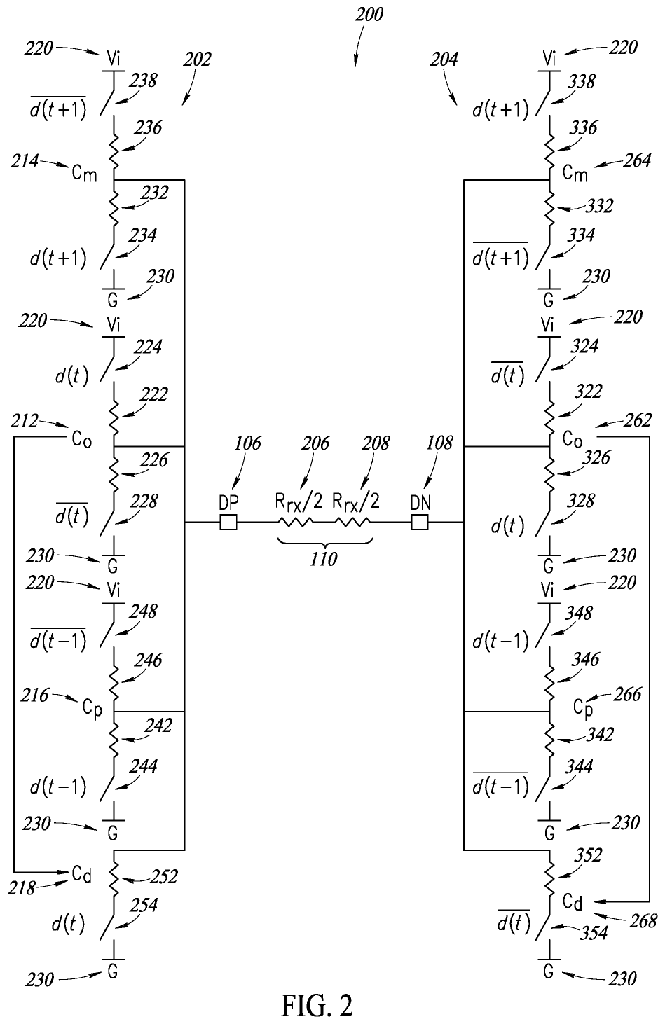

FIG. 2 shows a topology of a voltage driver 200 corresponding to the voltage driver 114 that is coupled to the positive and negative pads 106, 108 described in FIG. 1. In a differential voltage mode, a positive signal transmitted by the positive pad 106 is approximately in opposite phase with a negative signal transmitted by the negative pad 108. In this differential condition, the data is transmitted by a voltage difference between the positive and negative signals dropped on the load 110. Resistance blocks coupled to each of the positive pad 106 and the negative pad 108 are substantially symmetrical. Thus, the resistance of the load 110 (Rᵣₓ) is divided into two parts (Rᵣₓ/2) in which each part is matched to the resistance blocks of one of the positive and negative pads 106, 108. Consequently, resistance blocks 202 coupled to the positive pad 106 are designed to be symmetrical with resistance blocks 204 coupled to the negative pad 108.

The resistance blocks 202 include four resistive branches 212, 214, 216, and 218 coupled to the positive pad 106 in FIG. 2. However, the resistance blocks 202 may include any number of resistive branches. The first branch 212 includes a first resistance block 222 coupled between an input voltage 220 (represented as Vi in FIGS. 2-8) of the low voltage supply 116 described in FIG. 1 and the positive pad 106. The first resistance block 222 includes one or more resistors coupled to the input voltage 220 by a switch 224. The first branch 212 also includes a second resistance block 226 coupled between the ground 230 (G that corresponds to a zero-voltage level) and the positive pad 106. The second resistance block 226 includes one or more resistors coupled to the ground 230 by a switch 228. The state of the switch 224 is reversed or opposite to the state of the switch 228. For example, when the switch 224 is closed, then the switch 228 is open, and vice versa.

The second branch 214 includes a third resistance block 232 coupled between the ground 230 and the positive pad 106. The third resistance block 232 may include one or more resistors coupled to the ground 230 by a switch 234. The second branch 214 also includes a fourth resistance block 236 coupled between the input voltage 220 and the positive pad 106. The fourth resistance block 236 may include one or more resistors coupled to the input voltage 220 by a switch 238. In various embodiments, the state of the switch 234 is reversed or opposite to the state of the switch 238. In this condition, when the switch 234 is closed, then the switch 238 is open, and vice versa.

The third branch 216 includes a fifth resistance block 242 coupled between the ground 230 and the positive pad 106. The fifth resistance block 242 may include one or more resistors coupled to the ground 230 by a switch 244. The third branch 216 also includes a sixth resistance block 246 coupled between the input voltage 220 and the positive pad 106. The sixth resistance block 246 may include one or more resistors coupled to the input voltage 220 by a switch 248. In various embodiments, the state of the switch 244 is reversed or opposite to the state of the switch 248. In this condition, when the switch 244 is closed, then the switch 248 is open, and vice versa.

The fourth branch 218 includes a seventh resistance block 252 coupled between ground 230 and the positive pad 106. The seventh resistance block 252 may include one or more resistors coupled to the ground 230 by a switch 254. In various embodiments, the state of the switch 254 is the same as the state of the switch 224 of the first branch 212. In this condition, the switches 254 and 224 are closed or opened concurrently.

In some embodiments, the positive pad 106 is a positive display port, and the branches 212, 214, 216 of the resistance blocks 202 transfer video data to the positive display port. In this condition, the first branch 212 transfers a main cursor signal, which is a current bit of a display signal, to the positive display port; the second branch 214 transfers a pre-cursor signal, which is a future bit of the display signal, to the positive display port; and the third branch 216 transfers a post-cursor signal, which is a previous bit of the display signal, to the positive display port. Each of the first, second, and third branches 212, 214, 216 includes substantially the same resistance blocks and switches, while switches 224, 228 of the first branch 212 are activated (e.g., switched to be open or closed) at a time (t₀), switches 234, 238 of the second branch 214 are activated with a delay time (t₀+1), and switches 244, 248 of the third branch 216 are activated with a delay time (t₀−1). The fourth branch 218 includes the switch 254 that is activated concurrently with the switches 224, 228 at the time (t₀).

The resistance blocks 204 include four resistive branches 262, 264, 266, and 268 coupled to the negative pad 108. The circuit topology of the branches 262, 264, 266, and 268 is substantially the same as the topology of the branches 212, 214, 216, and 218, respectively, described above. The resistance blocks 204 may include any number of resistive branches. The branch 262 includes a resistance block 322 coupled between the input voltage 220 of the low voltage supply 116 described in FIG. 1 and the negative pad 108. The branch 262 includes one or more resistors coupled to the input voltage 220 by a switch 324. The branch 262 also includes a resistance block 326 coupled between ground 230 (G that corresponds to a zero-voltage level) and the negative pad 108. The resistance block 326 includes one or more resistors coupled to the ground 230 by a switch 328. The state of the switch 324 is reversed or opposite to the state of the switch 328. For example, when the switch 324 is closed, then the switch 328 is open, and vice versa.

The branch 264 includes a resistance block 332 coupled between the ground 230 and the negative pad 108. The resistance block 332 may include one or more resistors coupled to the ground 230 by a switch 334. The branch 264 also includes a resistance block 336 coupled between input voltage 220 and the negative pad 108. The resistance block 336 may include one or more resistors coupled to the input voltage 220 by a switch 338. In various embodiments, the state of the switch 334 is reversed or opposite to the state of the switch 338. In this condition, when the switch 334 is closed, then the switch 338 is open, and vice versa.

The branch 266 includes a resistance block 342 coupled between the ground 230 and the negative pad 108. The resistance block 342 may include one or more resistors coupled to the ground 230 by a switch 344. The branch 266 also includes a resistance block 346 coupled between the input voltage 220 and the negative pad 108. The resistance block 346 may include one or more resistors coupled to the input voltage 220 by a switch 348. In various embodiments, the state of the switch 344 is reversed or opposite to the state of the switch 348. In this condition, when the switch 344 is closed, then the switch 348 is open, and vice versa.

The branch 268 includes a resistance block 352 coupled between ground 230 and the negative pad 108. The resistance block 352 may include one or more resistors coupled to the ground 230 by a switch 354. In various embodiments, the state of the switch 354 is the same as the state of the switch 324 of the branch 262. In this condition, the switches 354 and 324 are closed or opened concurrently.

In some embodiments, the negative pad 108 is a negative display port, and the branches 262, 264, 266 of the resistance blocks 204 transfer video data to the negative display port. In this condition, the branch 262 transfers a main cursor signal, which is a current bit of a display signal, to the negative display port; the branch 264 transfers a pre-cursor signal, which is a future bit of the display signal, to the negative display port; and the branch 266 transfers a post-cursor signal, which is a previous bit of the display signal, to the negative display port. Each of the branches 262, 264, 266 includes substantially the same resistance blocks and switches, while switches 324, 328 of the branch 262 are activated (e.g., switched to be open or closed) at a time (t₀), switches 334, 338 of the branch 264 are activated with a delay time (t₀+1), and switches 344, 348 of the branch 266 are activated with a delay time (t₀−1). The branch 268 includes the switch 354 that is activated concurrently with the switches 324, 328 at the time (to).

A difference between the branches of the resistance blocks 202 and 204 is the input voltage from the low voltage supply 116 described in FIG. 1. In addition, timing of the switches is inverse compared with the branches of the resistance blocks 202. For instance, when the switch 224 is closed to couple the input voltage 220 into the positive pad 106, concurrently, a respective switch 328 in the branch 262 is closed to couple the ground 230 into the negative pad 108. Subsequently, when the switch 224 is open and the switch 228 is closed to couple the ground 230 into the positive pad 106, a respective switch 324 in the branch 262 is closed to couple the input voltage 220(Vi) into the negative pad 108. The other branches 264 and 266 also operate in a similar process for the other time periods.

The load 110 is coupled between the positive pad 106 and the negative pad 108. The resistance blocks 202 are substantially symmetrical with the resistance blocks 204, and the output impedance coupled to the resistance blocks 202 by the positive pad 106 is substantially symmetrical with the output impedance coupled to the resistance blocks 204 by the negative pad 108. Hence, half of the resistance value of the load 110 is coupled to the positive pad 106 to form an output impedance 206 coupled to the resistance blocks 202, and half of the resistance value of the load 110 is coupled to the negative pad 108 to form an output impedance 208 coupled to the resistance blocks 204. In various embodiments, the resistance value of the output impedance 206 is substantially the same as the output impedance 208. In this condition, impedance matching between the transmitter 102 and the receiver 104 described in FIG. 1 is met by design impedance values of the resistance blocks 202 and 204 to be substantially the same as the output impedances 206 and 208. The impedance matching optimizes transmission of data and power from the transmitter 102 to the receiver 104 by reducing reflection waves.

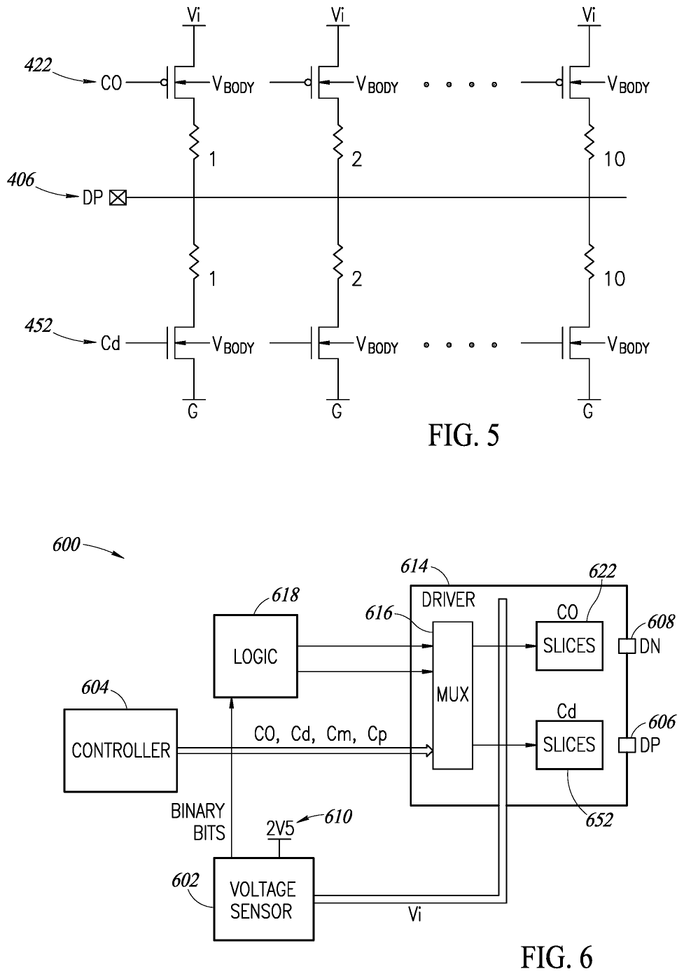

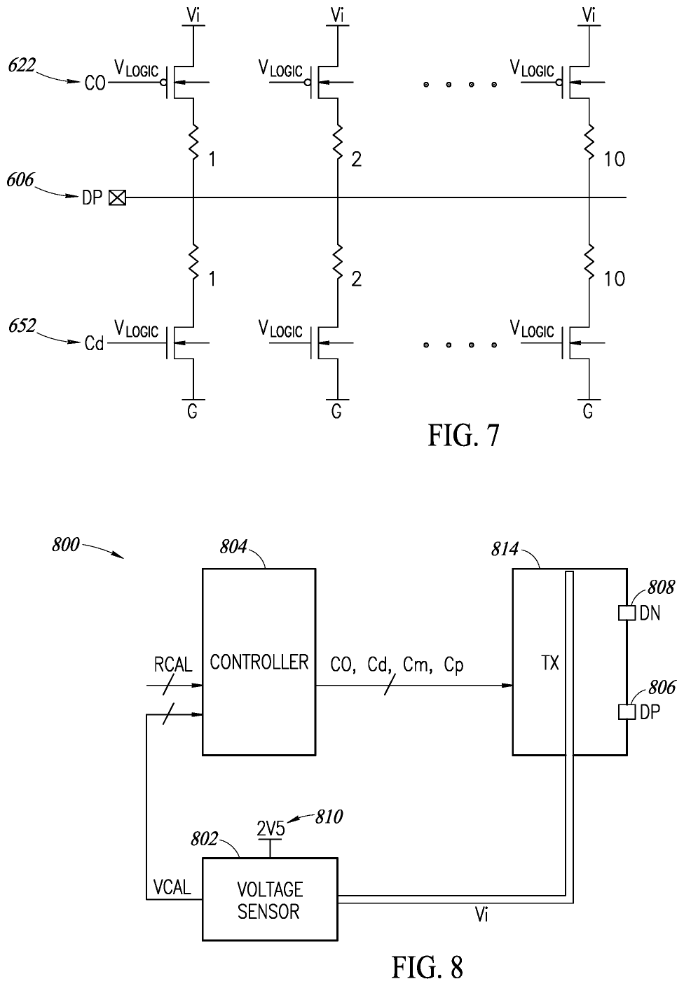

In various embodiments, each of the resistance blocks 222, 226, 232, 236, 242, 246, 252 of the resistance blocks 202, and the resistance blocks 322, 326, 332, 336, 342, 346, 352 of the resistance blocks 204 includes variable resistances. The variable resistances may include a plurality of resistors coupled together by metal-oxide-semiconductor field-effect transistors (MOSFETs). Each of the resistors and MOSFETs form a slice. An equivalent resistance of each resistance block is a result of a combination of a plurality of slices. In the embodiment shown in FIG. 2, each resistance block is shown by a resistor schematic for simplicity, however, each resistor schematic represents the equivalent resistance of the respective plurality of slices coupled to the resistance block. More detail of the resistors and MOSFETs combination in slices are described in embodiments of FIGS. 5 and 7.

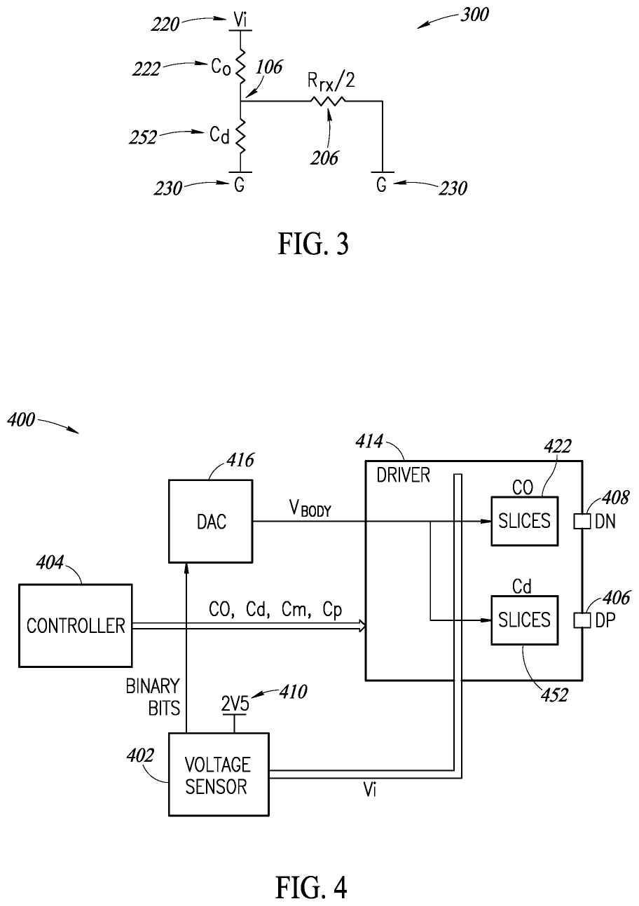

FIG. 3 is a resistive circuit 300 that shows an equivalent circuit of the resistance blocks 202 and the output impedance 206 of FIG. 2. In this embodiment, the switches 224 and 254 described in FIG. 2 are closed at the time (t₀), while the other switches are opened. In this embodiment, the first resistance block 222 is coupled between the input voltage 220 and the positive pad 106. The seventh resistance block 252 is coupled between the positive pad 106 and ground 230. The output impedance 206 is coupled between the positive pad 106 and ground 230. In various embodiments, the output impedance 206 is substantially half of the load 110 described in FIGS. 1 and 2. Hence, a voltage swing on the output impedance 206 is half of the value of the differential voltage swing of the circuit of the voltage driver 200 described in FIG. 2.

The respective switches in the resistance blocks 204 in FIG. 2 are in the same condition as described herein for the resistance blocks 202, thus only the circuit of the resistance blocks 202 is described for simplicity. For circuit analysis of the resistance blocks 202 coupled to the output impedance 206 that is substantially half of the load 110, and due to a substantially symmetrical condition between the positive pad 106 and the negative pad 108, a node between the output impedances 206 and 208 is virtually grounded to the ground 230. This virtual grounding helps to analyze each of the positive pad 106 and negative pad 108 separately and combine the results with a superposition of each equivalent circuit. In a symmetrical condition, an equivalent resistive circuit of the resistance blocks 204 is the same as the resistive circuit 300 described in FIG. 3.

In the embodiment of FIG. 3, a swing voltage on the output impedance 206 can be calculated by voltage dividing between the resistances of the resistance blocks 222, 252 and the output impedance 206. In various embodiments, each of the resistance blocks 222, 252 includes a plurality of slices. An equivalent resistance of each of the resistance blocks 222, 252 is adjustable by changing the number of the slices. In this embodiment, each slice has a constant resistance value R₀. By assuming that an equivalent resistance of the resistance block 222 is C₀ and an equivalent resistance of the resistance block 252 is C_{d}, while an equivalent resistance of each of the output impedances 206 and 208 is equal to a resistance value Rₜₑᵣₘ, the differential voltage swing that is twice the voltage swing on the output impedance 206 is calculated by Equation (1). The voltage swing refers to peak-to-peak difference between a positive cycle coupled to the output impedance 206 and a negative cycle coupled to the output impedance 208. Where two sides of the positive pad 106 and the negative pad 108 are symmetrical, as described in FIG. 2, the Equation (1) is derived based on a voltage division in the positive pad 106 side and then is multiplied by two to calculate peak-to-peak value.

$$Swing = \frac{2 Vi}{( C 0 + Cd ) + \frac{2 R 0}{term}} \qquad ( 1 )$$

In Equation (1), resistance values R₀ and Rₜₑᵣₘ are constant values. For instance, the resistance value R₀ is about 10 k ohms, and Rₜₑᵣₘ is about 50 ohms. In this condition, any change of the input voltage 220 (Vi) results in deviation of the differential voltage swing. From Equation (1), the deviation of the differential voltage swing may be compensated by changing the equivalent resistance C₀. In this condition, when the input voltage Vi increases, the equivalent resistance C₀ can be reduced respectively to compensate the increase of the input voltage Vi. In a same condition, when the input voltage Vi decreases, the equivalent resistance C₀ can be increased respectively to compensate the decrease of the input voltage Vi. However, changing the equivalent resistance C₀ alone may destroy the impedance matching between the positive pad 106 and the output impedance 206. In this embodiment, the impedance of the positive pad 106 is equivalent to a combination of the equivalent resistance C₀ and equivalent resistance C_{d}. Hence, changing the equivalent resistance C_{d} correspondence to any change of the equivalent resistance C₀ results in maintaining the impedance matching between the positive pad 106 and the output impedance 206 while compensating the deviation of the differential voltage swing.

In various embodiments, a summation of the equivalent resistances C₀ and C_{d} is set to remain at a constant value, while the value of the equivalent resistances C₀ is changed to compensate variations of the input voltage Vi. In some embodiments, a controller may change number of slices of the resistance blocks 222 and 252 corresponding to the variation of the Vi, while keeping the summation of the equivalent resistances C₀ and C_{d} in a constant value. The controller may change the resistance values of the slices directly by changing the variable resistances in each slice. For instance, when resistance value of the output impedance 206 is about 50 ohms, the equivalent resistances C₀ and C_{d} are adjusted to form an equivalent resistance 50 ohm at the positive pad 106 which results in impedance matching. In addition to the impedance matching, variations of the differential voltage swing of the Equation (1) are compensated by changing the equivalent resistances C₀.

FIG. 4 is a circuit diagram of a system 400 including the resistance blocks described in FIGS. 1-3. The system 400 may be a part of the transmitter 102 described in FIG. 1. In this embodiment, a voltage sensor 402 is coupled to a voltage driver 414. The voltage driver 414 corresponds to the voltage driver 114 described in FIG. 1. The voltage driver 414 outputs the differential signals described in FIG. 1 by a positive pad 406 and a negative pad 408. The voltage driver 414 includes resistance blocks such as the resistance blocks described in FIGS. 2 and 3. In various embodiments, the voltage driver 414 may include resistance blocks different than those described in FIGS. 2 and 3. In this embodiment, two resistance blocks 422 and 452 are included in the voltage driver 414 that corresponds to the resistance blocks 222/226 and 252 for a positive cycle coupled to the positive pad 406, and corresponds to the resistance blocks 322/326 and 352 for a negative cycle coupled to the negative pad 408, as described in FIGS. 2 and 3. The voltage driver 414 may include further resistance blocks that are not shown for simplicity.

The system 400 further includes a controller 404 coupled to the voltage driver 414. The controller 404 is configured to set resistance values of the resistance blocks in the voltage driver 414, e.g., slices of the resistance blocks 422 and 452. In this embodiment, the controller 404 may adjust the resistance blocks based on the impedance matching between the transmitter 102 and the receiver 104 described in FIG. 1. However, the controller 404 may not change the equivalent resistance values, e.g., the equivalent resistances C₀ and C_{d} during the operation of the system 400.

In this embodiment, the system 400 includes a digital-to-analog converter (DAC) 416 that is coupled between the voltage sensor 402 and the voltage driver 414. The voltage sensor 402 measures the input voltage of the resistance blocks 422, 452, e.g., input voltage Vi corresponding to the input voltage 220 described in FIGS. 2 and 3. In response to measuring the input voltage, the voltage sensor 402 generates and transmits a binary code to the digital-to-analog converter 416. The binary code indicates differences between the input voltage Vi and the reference voltage 410. In response to the binary code, the digital-to-analog converter 416 generates and transmits an analog signal V_{body} to the voltage driver 414. In various embodiments, the analog signal V_{body} refers to a voltage coupled to a body terminal of MOSFETs inside the resistance blocks 422 and 452 (more detail is described in FIG. 5). In various embodiments, the analog signal V_{body} changes equivalent resistances of the resistance blocks 422 and 452. In this condition, the analog signal V_{body} changes equivalent resistances C₀ and C_{d} based on the variation of measured input voltage (more detail is described in FIG. 5). Hence, a variation of the differential voltage swing is compensated by changing the equivalent resistance C₀, while the impedance of the voltage driver 414 remains matched with the receiver that is coupled to the positive pad 406 and negative pad 408 due to changing the equivalent resistance C₀ concurrent with the equivalent resistances C₀.

In various embodiments, the voltage sensor 402 may include a voltage comparator that compares the input voltage Vi with a reference voltage 410 to generate the binary code. For instance, the reference voltage 410 may be a target voltage of the input voltage Vi (e.g., 2.5 V or 1.2 V voltage supply). In this condition, when the measured voltage is less than the target voltage, then a binary code is generated to increase the equivalent resistances C₀ to compensate for the differential voltage swing, and decrease the equivalent resistances C_{d} to maintain the impedance matching between the transmitter 102 and the receiver 104 of FIG. 1. In contrast, when the measured voltage is greater than the target voltage, then a binary code is generated to decrease the equivalent resistances C₀ to compensate for the differential voltage swing, and increase the equivalent resistances C_{d} to maintain the impedance matching between the transmitter 102 and the receiver 104 of FIG. 1. In various embodiments, the controller 404 may set values of the various resistance blocks such as pre-cursor and post-cursor resistance blocks (Cₘ, Cₚ) described in FIG. 2. In this condition, the voltage sensor 402 generates binary code for pre-cursor and post-cursor in addition to the main cursor (C₀).

In some embodiments, the voltage sensor may generate the binary code as an 11-bit digital data (e.g., DATA |10:0|). In this condition, the digital-to-analog converter 416 receives the 11-bit binary code and generates the analog signal V_{body} based on a reference voltage (e.g., bandgap reference voltage VBG with a voltage of about 2.5 V or 1.2 V). Equation (2) represents generating the analog signal V_{body} based on the 11-bit binary code and the reference voltage VBG. The dominator of the Equation (2) represents number of values that can be generated for the 11-bit binary code.

$${V}_{b o d y} = \frac{dig \{ DATA \vert 10 : 0 \vert \} \times 2 \times VBG}{2047} \qquad ( 2 )$$

In various embodiments, the circuit diagram of the system 400 may be formed as a Fully Depleted Silicon on Insulator (FDSOI) integrated circuit. In some embodiments, the voltage sensor 402 may be a voltage/thermal sensor or any sensor/compensation cell which tracks the input voltage Vi and generates the binary codes. The controller 404 may be a microprocessor or any other types of the integrated processors.

FIG. 5 is an example of the slices of the resistance blocks 422 and 452 described in FIG. 4. In this embodiment, each slice includes a MOS transistor and a resistor. In various embodiments, the resistors and the MOS transistors of the slices in each resistance block are the same. The number of slices depends on variations of the equivalent resistances that satisfy the differential voltage swing. For instance, each of the resistance blocks 422 and 452 may include 10 slices that are controlled by the analog signal V_{body} described in FIG. 4.

In this embodiment, the resistance block 422 (C₀) includes 10 slices. Each slice of the resistance block 422 includes a PMOS transistor coupled between the input voltage Vi and a resistor. The resistor is coupled to the positive pad 406. In this condition, an equivalent resistance of each slice is changing by the analog signal V_{body} that is coupled to body terminals of each PMOS transistor. The 10 slices form parallel resistances that result in an equivalent resistance of the resistance block 422. In a same condition, the resistance block 452 (C_{d}) includes 10 slices. Each slice of the resistance block 452 includes an NMOS transistor coupled between the ground and a resistor. The resistor is coupled to the positive pad 406. In this condition, an equivalent resistance of each slice is changing by the analog signal V_{body} that is coupled to body terminals of each NMOS transistor. The 10 slices form parallel resistances that result in an equivalent resistance of the resistance block 452. The equivalent resistance coupled to the positive pad 406 is a result of a combination between the equivalent resistances of the resistance blocks 422 and 452. Hence, the equivalent resistance is adjustable by the signal V_{body}. In various embodiments, the transistors of the slices in resistance block 422 may include NMOS and the transistors of the slices in resistance block 452 may include PMOS. The same circuit topology may be coupled to the negative pad 408. In some embodiments, gate terminals of the NMOS and PMOS transistors may be controlled by the controller 404 described in FIG. 4, in which the controller 404 sets resistance values of the resistance blocks 422 and 452.

In one example, the analog signal V_{body} is a positive voltage in response to an increase of the input voltage Vi. In this example, the voltage sensor 402 detects that the input voltage Vi is greater than the reference voltage 410, and in response, generates binary bits indicative of the increased value of the input voltage Vi compare with the reference voltage 410, as described in FIG. 4. The digital-to-analog converter 416 receives the binary bits and generates a positive voltage of the analog signal V_{body}. The positive voltage is coupled to the body terminals of the PMOS transistors in resistance block 422 and decreases the equivalent resistance of the resistance block 422 (C₀ in Equation (1)). The same positive voltage is coupled to the body terminals of NMOS transistors in resistance block 452 and decreases the equivalent resistance of the resistance block 422 (C_{d} in Equation (1)). An inverse condition may happen when the input voltage Vi is decreased and the analog signal V_{body} is a negative voltage.

FIG. 6 is a circuit diagram of a system 600 including the resistance blocks described in FIGS. 1-3. The system 600 may be a part of the transmitter 102 described in FIG. 1. In this embodiment, a voltage sensor 602 is coupled to a voltage driver 614. The voltage driver 614 corresponds to the voltage driver 114 described in FIG. 1. The voltage driver 614 outputs the differential signals described in FIG. 1 by a positive pad 606 and a negative pad 608. The voltage driver 614 includes resistance blocks such as the resistance blocks described in FIGS. 2 and 3. In this embodiment, two resistance blocks 622 and 652 are included in the voltage driver 614 that corresponds to the resistance blocks 222 and 252 for a positive cycle coupled to the positive pad 606, and corresponds to the resistance blocks 322 and 352 for a negative cycle coupled to the negative pad 608, as described in FIGS. 2 and 3. The voltage driver 614 may include further resistance blocks that are not shown for simplicity. In various embodiments, the voltage driver 614 may include resistance blocks different than those described in FIGS. 2 and 3. In this embodiment, the voltage driver 614 further includes a multiplexer 616. The multiplexer 616 is coupled to the resistance blocks 622 and 652.

The system 600 further includes a controller 604 coupled to the voltage driver 614. The controller 604 is configured to set resistance values of the resistance blocks in the voltage driver 614, e.g., slices of the resistance blocks 622 and 652. An output of the controller 604 is coupled to the multiplexer 616. In this condition, the controller 604 may adjust the resistance blocks based on the impedance matching between the transmitter 102 and the receiver 104 described in FIG. 1. However, the controller 604 may not change the equivalent resistance values, e.g., the equivalent resistances C₀ and C_{d} during the operation of the circuit diagram of the system 600.

A main difference between this embodiment with the embodiment of FIG. 4 is changing the equivalent resistances with a digital signal instead of the analog signal V_{body} described in FIGS. 4 and 5. The digital signal changes the equivalent resistances by turning on/off the NMOS and PMOS transistors of the resistance blocks 622, 652. In this embodiment, the system 600 includes a logic module 618 that is coupled between the voltage sensor 602 and the voltage driver 614. The voltage sensor 602 measures the input voltage of the resistance blocks 622, 652, e.g., input voltage Vi correspondence to the input voltage 220 described in FIGS. 2 and 3. In response to the measuring the input voltage, the voltage sensor 602 generates and transmits a binary code to the logic module 618. The binary code indicates differences between the input voltage Vi and the reference voltage 610. In response to the binary code, the logic module 618 generates and transmits a logic code to the multiplexer 616 of the voltage driver 614. The logic code may be in binary or decimal format which depends on differences between the input voltage Vi and the reference voltage 610. In various embodiments, the multiplexer 616 generates logical voltage levels based on the received logic codes from the controller 604 and the logic module 618. The logical voltage levels are coupled to a gate terminal of the MOSFETs in the slices of resistance blocks 622 and 652. In this condition, the logical voltage levels change equivalent resistances C₀ and C_{d} based on the variation of measured input voltage. Hence, a variation of the differential voltage swing is compensated by changing the equivalent resistance C₀, while the impedance of the voltage driver 614 remains matched with the receiver that is coupled to the positive pad 606 and negative pad 608 due to changing the equivalent resistance C₀ concurrent with the equivalent resistances C₀.

In various embodiments, the voltage sensor 602 may include a voltage comparator that compares the input voltage Vi with a reference voltage 610 to generate the binary code. For instance, the reference voltage 610 may be a target voltage of the input voltage Vi (e.g., 2.5 V or 1.2 V voltage supply). In this condition, when the measured voltage is less than the target voltage, a binary code is generated to increase the equivalent resistances C₀ to compensate for the differential voltage swing, and decrease the equivalent resistances C_{d} to maintain the impedance matching between the transmitter 102 and the receiver 104 of FIG. 1. In contrast, when the measured voltage is greater than the target voltage, then a binary code is generated to decrease the equivalent resistances C₀ to compensate for the differential voltage swing, and increase the equivalent resistances C_{d} to maintain the impedance matching between the transmitter 102 and the receiver 104 of FIG. 1. In various embodiments, the controller 604 may set values of the various resistance blocks such as pre-cursor and post-cursor resistance blocks (Cₘ, Cₚ) described in FIG. 2. In this condition, the voltage sensor 602 generates binary code for pre-cursor and post-cursor in addition to the main cursor (C₀). Compared with the embodiment described in FIG. 4, the embodiment of FIG. 6 uses logical codes instead of the analog signal, to mitigate the equivalent resistance values of the resistance blocks 622 and 652. Using the logical code instead of the analog signal may reduce power consumption of the system 600, as well as increase speed and accuracy of the resistance changes.

FIG. 7 is an example of the slices of the resistance blocks 622 and 652 described in FIG. 6. In this embodiment, each slice includes a MOS transistor and a resistor. In various embodiments, the resistors and the MOS transistors of the slices in each resistance block are the same. The number of slices depends on variations of the equivalent resistances that satisfy the differential voltage swing. For instance, each of the resistance blocks 622 and 652 may include 10 slices that are controlled by the logical voltage levels described in FIG. 6.

In this embodiment, the resistance block 622 (C₀) includes 10 slices. Each slice of the resistance block 622 includes a PMOS transistor coupled between the input voltage Vi and a resistor. The resistor is coupled to the positive pad 606. In this condition, an equivalent resistance of each slice is changing by the logical level voltages (V_{logic}) that is coupled to gate terminals of each PMOS transistor. The 10 slices form parallel resistances that result in an equivalent resistance of the resistance block 622. In a same condition, the resistance block 652 (C_{d}) includes 10 slices. Each slice of the resistance block 652 includes an NMOS transistor coupled between the ground and a resistor. The resistor is coupled to the positive pad 606. In this condition, an equivalent resistance of each slice is changing by the logical level voltages (V_{logic}) that is coupled to gate terminals of each NMOS transistor. The 10 slices form parallel resistances that result in an equivalent resistance of the resistance block 652. The equivalent resistance coupled to the positive pad 606 is a result of a combination between the equivalent resistances of the resistance blocks 622 and 652. Hence, the equivalent resistance is adjustable by the logical level voltages (V_{logic}). In various embodiments, the transistors of the slices in resistance block 622 may include NMOS and the transistors of the slices in resistance block 652 may include PMOS. The same circuit topology may be coupled to the negative pad 608.

In one example, the logic code is a value in response to an increase of the input voltage Vi. In this example, the voltage sensor 602 detects that the input voltage Vi is greater than the reference voltage 610, and in response, generates binary bits indicative of the increased value of the input voltage Vi compare with the reference voltage 610, as describe in FIG. 6. The logic module 618 receives the binary bits and generates a logic code corresponding to the binary bits. The logic code results in the multiplexer 616 generates a high logical level output to be coupled to the gate terminals of one or more of the PMOS transistors in resistance block 622 and turn off the respective PMOS transistors that consequently decrease the equivalent resistance of the resistance block 622 (C₀ in Equation (1)). The same high logical level output is coupled to the gate terminals of one or more of the NMOS transistors in resistance block 522 and turn on the respective NMOS transistors that consequently increase the equivalent resistance of the resistance block 652 (C_{d} in Equation (1)). An inverse condition may happen when the input voltage Vi is decreased and the output of the multiplexer 616 is a low logical level.

FIG. 8 is a circuit diagram of a system 800 including the resistance blocks described in FIGS. 1-3. The system 800 may be a part of the transmitter 102 described in FIG. 1. In this embodiment, a voltage sensor 802 is coupled to a voltage driver 814. The voltage driver 814 corresponds to the voltage driver 114 described in FIG. 1. The voltage driver 814 outputs the differential signals described in FIG. 1 by a positive pad 806 and a negative pad 808. The voltage driver 614 includes resistance blocks such as the resistance blocks described in FIGS. 2 and 3. In this embodiment, the resistance blocks are not shown for simplicity, however, they may include the same resistance blocks as described in FIGS. 4-7.

The system 800 further includes a controller 804 coupled to the voltage driver 814. The controller 804 is configured to set resistance values of the resistance blocks in the voltage driver 814. In this condition, the controller 804 may adjust the resistance blocks based on the impedance matching between the transmitter 102 and the receiver 104 described in FIG. 1. In addition, the controller 804 may change the equivalent resistance values, e.g., the equivalent resistances C₀ and C_{d} during the operation of the system 800. Hence, in this embodiment, the digital-to-analog converter 416 of FIG. 4 or the logic module 618 of FIG. 6 are not used.

A main difference between this embodiment with the embodiment of FIGS. 4-6 is changing the equivalent resistances with a digital signal directly generated by the controller instead of the analog signal V_{body} described in FIGS. 4 and 5. The digital signal changes the equivalent resistances by turning on/off the NMOS and PMOS transistors of the resistance blocks 622, 652. In this embodiment, the voltage sensor 802 measures the input voltage of the resistance blocks, e.g., input voltage Vi correspondence to the input voltage 220 described in FIGS. 2 and 3. In response to measuring the input voltage, the voltage sensor 802 generates and transmits a calibration code (VCAL) to the controller 804. In response to the calibration code, the controller 804 generates and transmits a logic code to the voltage driver 814. The logic code may be substantially the same as the logic code generated by the logic module 618 in FIG. 6 to be coupled to a multiplexer inside the voltage driver 814 (not shown). In addition, the logic code may be substantially the same as the logical level voltages described as the output of the multiplexer 616 in FIG. 6. In various embodiments, the logic code is coupled to a gate terminal of the MOSFETs in the slices of resistance blocks. In this condition, the logic code changes equivalent resistances C₀ and C_{d} based on the variation of measured input voltage. Hence, a variation of the differential voltage swing is compensated by changing the equivalent resistance C₀, while the impedance of the voltage driver 814 remains matched with the receiver that is coupled to the positive pad 806 and negative pad 808 due to changing the equivalent resistance C₀ concurrent with the equivalent resistances C₀.

In various embodiments, the voltage sensor 802 may include a voltage comparator that compares the input voltage Vi with a reference voltage 810 to generate the binary code. For instance, the reference voltage 810 may be a target voltage of the input voltage Vi (e.g., 2.5 V voltage supply). In this condition, when the measured voltage is less than the target voltage, then a calibration code is generated to increase the equivalent resistances C₀ to compensate for the differential voltage swing, and decrease the equivalent resistances C_{d} to maintain the impedance matching between the transmitter 102 and the receiver 104 of FIG. 1. In contrast, when the measured voltage is greater than the target voltage, then a calibration code is generated to decrease the equivalent resistances C₀ to compensate for the differential voltage swing, and increase the equivalent resistances C_{d} to maintain the impedance matching between the transmitter 102 and the receiver 104 of FIG. 1. In various embodiments, the controller 804 may set values of the various resistance blocks such as pre-cursor and post-cursor resistance blocks (Cₘ, Cₚ) described in FIG. 2. In this condition, the voltage sensor 802 generates calibration codes for pre-cursor and post-cursor in addition to the main cursor (C₀). In some embodiments, the controller 804 sets the values of the various resistance blocks by receiving a calibration code (RCAL). The calibration code may be received from an external device or input/output interface. In this condition, the calibration code (RCAL) sets the values of the various resistance blocks, while the calibration code (VCAL) determines variation of the equivalent resistance to compensate for the differential voltage swing as well as maintain the impedance matching. For instance, in a transmitter for a display, the calibration process may be repeated at the beginning of transferring each frame of a video signal.

In one example, the circuit in the voltage driver 814 is substantially the same as the circuit described in FIG. 7. In this condition, the logic code generated by the controller 804 is a value in response to an increase of the input voltage Vi. In this example, the voltage sensor 802 detects that the input voltage Vi is greater than the reference voltage 810, and in response, generates the calibration code (VCAL) indicative of the increased value of the input voltage Vi compare with the reference voltage 810. The controller 804 receives the calibration code (VCAL) and generates a logic code corresponding to the calibration code (VCAL). The logic code results in a multiplexer inside the voltage driver 814 that corresponds to the multiplexer 616 in FIG. 6 generates a high logical level output to be coupled to the gate terminals of one or more of the PMOS transistors in resistance block 622 and turn off the respective PMOS transistors that consequently decrease the equivalent resistance of the resistance block 622 (C₀ in Equation (1)). The same high logical level outputs are coupled to the gate terminals of one or more of the NMOS transistors in resistance block 522 and turn on the respective NMOS transistors that consequently increase the equivalent resistance of the resistance block 652 (C_{d} in Equation (1)). Alternatively, the logical code at the output of the controller 804 may be logical level outputs to directly couple into the gate terminals of the PMOS and NMOS transistors. An inverse condition may happen when the input voltage Vi is decreased and the output of the multiplexer or the controller 804 is a low logical level.

Compared with the embodiment described in FIGS. 4 and 6, the embodiment of FIG. 8 is simplified due to removing the digital-to-analog converter 416 of FIG. 4 or the logic module 618 of FIG. 6. However, the process in the controller 804 may be more complex than the process described in FIGS. 4 and 6, and consequently results in greater time and energy consumption than the embodiments of FIGS. 4-6.

A device may be summarized as including a voltage driver including: first and second outputs, the first output is positive and the second output is negative, and a difference between the first and second outputs generates a differential voltage swing; a first branch having a first resistor and a first switch, the first resistor is coupled to an input voltage by the first switch, the first resistor is coupled to the first output, the first branch having a second resistor and a second switch, the second resistor is coupled to ground by the second switch, the second resistor is coupled to the first output; a second branch having a third resistor and a third switch, the third resistor is coupled to the ground by the third switch, the third resistor is coupled to the first output; and a voltage sensor configured to detect the input voltage, and generate a code based on the detected input voltage, resistance values of the first and third resistors being calibrated based on the code to maintain a constant summation of the first and third resistors.

The voltage driver may further include a third branch having a fourth resistor and a fourth switch, the fourth resistor is coupled to the input voltage by the fourth switch, the fourth resistor is coupled to the second output, the third branch having a fifth resistor and a fifth switch, the fifth resistor is coupled to the ground by the fifth switch, the fifth resistor is coupled to the second output; and a fourth branch having a sixth resistor and a sixth switch, the sixth resistor is coupled to the ground by the sixth switch, the sixth resistor is coupled to the second output, and the fourth and sixth switches are closed concurrently or opened concurrently.

The second switch may have an open state when the first and third switches have close states and the fourth switch has an open state, and the second switch may have a close state when the first and third switches have open states and the fourth switch has a close state.

The voltage driver may further include a third branch having a fourth resistor and a fourth switch, the fourth resistor is coupled to the input voltage by the fourth switch, the fourth resistor is coupled to the first output, the third branch having a fifth resistor and a fifth switch, the fifth resistor is coupled to the ground by the fifth switch, the fifth resistor is coupled to the first output; and a fourth branch having a sixth resistor and a sixth switch, the sixth resistor is coupled to the input voltage by the sixth switch, the sixth resistor is coupled to the first output, the fourth branch having a seventh resistor and a seventh switch, the seventh resistor is coupled to the ground by the seventh switch, the seventh resistor is coupled to the first output.

The device may be a high-speed point-to-point communications system operating in a physical layer (PHY) protocol.

The first and second outputs of the voltage driver may be coupled to a receiver load.

The resistance values of the first and third resistors may be calibrated to compensate for the differential voltage swing between the first and second outputs.

The device may further include a digital-to-analog converter coupled between the voltage sensor and the voltage driver, the digital-to-analog converter being configured to receive the code from the voltage sensor, and transmit an analog signal to the voltage driver corresponding to the code, the analog signal calibrates the resistance values of the first and third resistors.

The device may further include a logic circuit coupled between the voltage sensor and the voltage driver, the logic circuit being configured to receive the code from the voltage sensor, and transmit a logical code to the voltage driver corresponding to the received code, the logical code calibrates the resistance values of the first and third resistors.

The device may further include a controller coupled between the voltage sensor and the voltage driver, the controller being configured to receive the code from the voltage sensor, and transmit a logical code to the voltage driver corresponding to the received code, the logical code calibrates the resistance values of the first and third resistors.

A method may be summarized as including measuring, by a voltage sensor, an input voltage of a voltage driver; performing a comparison between the measured input voltage and a threshold voltage; generating, by the voltage sensor, a code based on the comparison; transmitting the code to the voltage driver; and altering resistances of the voltage driver based on the code, the altering resistances compensates for a differential voltage swing, wherein an output impedance of the voltage driver remains substantially constant.

The changing of the resistances may include increasing a first resistance and reducing a second resistance when the measured input voltage is less than the threshold voltage; and reducing the first resistance and increasing the second resistance when the measured voltage is greater than the threshold voltage.

The changing of the resistances may cause a summation of the first and second resistances remaining a substantially constant value.

The output impedance of the voltage driver may be substantially the same as the constant value, and a load may be coupled to an output of the voltage driver, impedance of the load being the same as the constant value.

The method may include generating binary codes based on the code; transmitting the binary code to a digital-to-analog converter; and transmitting an analog signal corresponding to the binary code to the voltage driver, the analog signal changes the resistance of the voltage driver.

The generating of the code may include generating binary codes; transmitting the binary code to a logic module; transmitting a calibration code corresponding to the binary code to a multiplexer of the voltage driver; and coupling a logical voltage level to resistance blocks of the first and second resistances, the logical voltage level changes the first and second resistances corresponding to the binary codes.

A system may be summarized as including a receiver having a load; a transmitter having serial inputs and differential outputs, the differential outputs include a first output and a second output, the load being coupled to the first and second outputs, the transmitter including: a voltage driver having first and second resistance blocks, the first resistance block coupled to the first output and the second resistance block coupled to the second output; a voltage sensor to detect variations of an input voltage of the voltage driver; and a controller configured to change equivalent resistances of the first and second resistance blocks based on the detected variations, the equivalent resistances remaining substantially the same as the load.

The device may be a high-speed point-to-point communications system operating in a physical layer (PHY) protocol.

The change equivalent resistances of the first and second resistance blocks may cause to compensate for a differential voltage swing between the first and second outputs.

The transmitter may further include a digital-to-analog converter configured to receive a binary code from the voltage sensor and transmit an analog signal to the voltage driver, the analog signal causes the change of the first and second resistance blocks.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a voltage driver including:
first and second outputs, the first output is a positive terminal and the second output is a negative terminal, a difference between signals on the first and second outputs configured to generate a differential voltage swing;
a first branch having a first resistor and a first switch, the first resistor is coupled to an input voltage by the first switch, the first resistor is coupled to the first output, the first branch having a second resistor and a second switch, the second resistor is coupled to ground by the second switch, the second resistor is coupled to the first output;
a second branch having a third resistor and a third switch, the third resistor is coupled to ground by the third switch, the third resistor is coupled to the first output; and
a voltage sensor configured to detect the input voltage, and generate a code based on the detected input voltage, resistance values of the first and third resistors configured to be calibrated based on the code to maintain a constant summation of the first and third resistors.

2. The device of claim 1, wherein the voltage driver further includes:
a third branch having a fourth resistor and a fourth switch, the fourth resistor is coupled to the input voltage by the fourth switch, the fourth resistor is coupled to the second output, the third branch having a fifth resistor and a fifth switch, the fifth resistor is coupled to ground by the fifth switch, the fifth resistor is coupled to the second output; and
a fourth branch having a sixth resistor and a sixth switch, the sixth resistor is coupled to ground by the sixth switch, the sixth resistor is coupled to the second output, and the fourth and sixth switches are configured to be closed concurrently or opened concurrently.

3. The device of claim 2, wherein the second switch has an open state in response to the first and third switches having closed states and the fourth switch has an open state, and the second switch has a close state in response to the first and third switches having open states and the fourth switch has a closed state.

4. The device of claim 1, wherein the voltage driver further includes:
a third branch having a fourth resistor and a fourth switch, the fourth resistor is coupled to the input voltage by the fourth switch, the fourth resistor is coupled to the first output, the third branch having a fifth resistor and a fifth switch, the fifth resistor is coupled to ground by the fifth switch, the fifth resistor is coupled to the first output; and
a fourth branch having a sixth resistor and a sixth switch, the sixth resistor is coupled to the input voltage by the sixth switch, the sixth resistor is coupled to the first output, the fourth branch having a seventh resistor and a seventh switch, the seventh resistor is coupled to ground by the seventh switch, the seventh resistor is coupled to the first output.

5. The device of claim 1, wherein the device is a high-speed point-to-point communications system operating in a physical layer (PHY) protocol.

6. The device of claim 5, wherein the first and second outputs of the voltage driver are coupled to a receiver load.

7. The device of claim 1, wherein the resistance values of the first and third resistors are calibrated to compensate for the differential voltage swing between the first and second outputs.

8. The device of claim 1, further comprising:
a digital-to-analog converter coupled between the voltage sensor and the voltage driver, the digital-to-analog converter configured to receive the code from the voltage sensor, and transmit an analog signal to the voltage driver corresponding to the code, the analog signal calibrates the resistance values of the first and third resistors.

9. The device of claim 1, further comprising:
a logic circuit coupled between the voltage sensor and the voltage driver, the logic circuit configured to receive the code from the voltage sensor, and transmit a logical code to the voltage driver corresponding to the received code, the logical code calibrates the resistance values of the first and third resistors.

10. The device of claim 1, further comprising:
a controller coupled between the voltage sensor and the voltage driver, the controller configured to receive the code from the voltage sensor, and transmit a logical code to the voltage driver corresponding to the received code, the logical code calibrates the resistance values of the first and third resistors.

11. A method, comprising:
measuring, by a voltage sensor, an input voltage of a voltage driver;
performing a comparison between the measured input voltage and a threshold voltage;
generating, by the voltage sensor, a code based on the comparison;
transmitting the code to the voltage driver; and
altering resistances of the voltage driver based on the code, the altering resistances compensates for a differential voltage swing, wherein an output impedance of the voltage driver remains substantially constant.

12. The method of claim 11, wherein the changing of the resistances includes:
increasing a first resistance and reducing a second resistance in response to the measured input voltage being less than the threshold voltage; and
reducing the first resistance and increasing the second resistance in response to the measured voltage being greater than the threshold voltage.

13. The method of claim 12, wherein the changing of the resistances causes a summation of the first and second resistances remaining a substantially constant value.

14. The method of claim 13, wherein the output impedance of the voltage driver is substantially the same as the constant value, and a load is coupled to an output of the voltage driver, impedance of the load being the same as the constant value.

15. The method of claim 11, comprising:
generating binary codes based on the code;
transmitting the binary code to a digital-to-analog converter; and
transmitting an analog signal corresponding to the binary code to the voltage driver, the analog signal changes the resistance of the voltage driver.

16. The method of claim 12, wherein the generating of the code includes:
generating binary codes;
transmitting the binary code to a logic module;
transmitting a calibration code corresponding to the binary code to a multiplexer of the voltage driver; and
coupling a logical voltage level to resistance blocks of the first and second resistances, the logical voltage level changes the first and second resistances corresponding to the binary codes.

17. A system, comprising:
a receiver having a load;
a transmitter having serial inputs and differential outputs, the differential outputs include a first output and a second output, the load being coupled to the first and second outputs, the transmitter including:
a voltage driver having first and second resistance blocks, the first resistance block coupled to the first output and the second resistance block coupled to the second output;
a voltage sensor configured to detect variations of an input voltage of the voltage driver; and
a controller configured to change equivalent resistances of the first and second resistance blocks based on the detected variations, the equivalent resistances remaining substantially the same as the load.

18. The system of claim 17, wherein the device is a high-speed point-to-point communications system operating in a physical layer (PHY) protocol.

19. The system of claim 17, wherein the change equivalent resistances of the first and second resistance blocks causes to compensate for a differential voltage swing between the first and second outputs.

20. The system of claim 17, wherein the transmitter further includes:
a digital-to-analog converter configured to receive a binary code from the voltage sensor and transmit an analog signal to the voltage driver, the analog signal causes the change of the first and second resistance blocks.
